(19) United States
(12) Patent Application Publication
(10) Pub. No.: US 2025/0277865 A1
(43) Pub. Date: Sep. 4, 2025

(54) METHOD OF MEASURING IMPEDANCE PARAMETER AND IMPEDANCE PARAMETER MEASUREMENT DEVICE

(71) Applicants: MURATA MANUFACTURING CO., LTD., Kyoto (JP); TOKYO UNIVERSITY OF SCIENCE FOUNDATION, Tokyo (JP)

(72) Inventors: Jusuke SHIMURA, Kyoto (JP); Masayuki ITAGAKI, Kyoto (JP)

(21) Appl. No.: 19/213,679

(22) Filed: May 20, 2025

Related U.S. Application Data
(63) Continuation of application No. PCT/JP2024/000571, filed on Jan. 12, 2024.

(30) Foreign Application Priority Data
Feb. 20, 2023 (JP) 2023-024160

(51) Int. Cl. G01R 31/389; G01R 31/36; G01R 31/3835

(52) U.S. Cl. CPC G01R 31/389; G01R 31/3648; G01R 31/3835

(57) ABSTRACT

A method of measuring an impedance parameter is provided and includes:

(A) making a step change in current of the electrochemical device;

(B) performing measurement of a voltage of the electrochemical device at multiple different timings during a transient response of the voltage of the electrochemical device caused by making the step change in the current of the electrochemical device; and

(C) deriving a p constant of the CPE, based on multiple voltage values determined through the measurement, and deriving a T constant of the CPE, based on the derived p constant and the multiple voltage values determined through the measurement.

### CROSS REFERENCE TO RELATED APPLICATIONS

The present application is a continuation of International Application No. PCT/JP2024/000571, filed on Jan. 12, 2024, which claims priority to Japanese Patent Application No. 2023-024160, filed on Feb. 20, 2023, the entire contents of which are incorporated herein by reference.

### BACKGROUND

The present technology relates to a method of measuring an impedance parameter, and to an impedance parameter measurement device.

Electric vehicles and hybrid vehicles have been widely used. Power generation devices for solar power generation or wind power generation in which power generation is unstable and necessitates leveling have also been widely used. Such widespread use has rapidly increased demand for lithium-ion secondary batteries.

A battery module including many lithium-ion batteries has an issue of decreased safety caused by an abnormal lithium-ion battery mixed therein. One known degradation mode of the lithium-ion battery is a degradation mode in which an electric double layer capacitance greatly changes. It is possible to detect an abnormal lithium-ion battery that degrades due to the degradation mode described above with a focus on a difference in the electric double layer capacitance.

The electric double layer capacitance of the lithium-ion battery is represented by an electric circuit including a constant phase element (CPE) in some cases.

The CPE is an element having two constants, i.e., a p constant representing a characteristic as the element and a T constant representing a physical property value. For example, a method is disclosed of determining the p constant and the T constant in a time domain.

### SUMMARY

The present technology relates to a method of measuring an impedance parameter, and to an impedance parameter measurement device.

In the method described in the Background section there is an issue that it takes long calculation time to calculate a behavior in a time domain of an electric circuit including a CPE. It is desirable to provide a method of measuring an impedance parameter and an impedance parameter measurement device each of which makes it possible to measure a p constant and a T constant while achieving reduction in the calculation time according to an embodiment.

A method of measuring an impedance parameter according to an embodiment of the present technology is a method of measuring an impedance parameter of an electrochemical device represented by an equivalent circuit that is an electric circuit including a constant phase element (CPE). The method of measuring the impedance parameter includes the following three processes according to an embodiment:
(A) making a step change in current of the electrochemical device;
(B) performing measurement of a voltage of the electrochemical device at multiple different timings during a transient response of the voltage of the electrochemical device caused by making the step change in the current of the electrochemical device; and
(C) deriving a p constant of the CPE, based on multiple voltage values determined through the measurement, and deriving a T constant of the CPE, based on the derived p constant and the multiple voltage values determined through the measurement.

An impedance parameter measurement device according to an embodiment of the present technology is a device configured to measure an impedance parameter of an electrochemical device represented by an equivalent circuit that is an electric circuit including a CPE. The impedance parameter measurement device includes a current source, a measurement circuit, and a signal processor. The current source is configured to make a step change in current of the electrochemical device. The measurement circuit is configured to perform measurement of a voltage of the electrochemical device at multiple different timings during a transient response of the voltage of the electrochemical device caused by making the step change in the current of the electrochemical device. The signal processor is configured to derive a p constant of the CPE, based on multiple voltage values determined through the measurement and to derive a T constant of the CPE, based on the derived p constant and the multiple voltage values determined through the measurement.

In the method of measuring the impedance parameter according to an embodiment of the present technology and the impedance parameter measurement device according to an embodiment of the present technology, the measurement of the voltage of the electrochemical device represented by the equivalent circuit that is the electric circuit including the CPE is performed at the multiple different timings during the transient response of the voltage of the electrochemical device caused by making the step change in the current of the electrochemical device. Thereafter, the p constant of the CPE is derived, based on the multiple voltage values determined through the measurement, and the T constant of the CPE is derived, based on the derived p constant and the multiple voltage values determined through the measurement. This makes it possible to measure the p constant and the T constant while achieving reduction in calculation time.

Note that effects of the present technology are not necessarily limited to those described herein and may include any of a series of effects in relation to the present technology.

### BRIEF DESCRIPTION OF THE FIGURES

FIG. 1 is a diagram illustrating an example of an equivalent circuit of an electrochemical device.

FIG. 2 is a diagram illustrating an example of an expression of a voltage response of the equivalent circuit in FIG. 1.

FIG. 3 is a plot illustrating, in a double linear scale, an example of the voltage response of the equivalent circuit derived from the expression of the voltage response in FIG. 2.

FIG. 4 is a plot illustrating, in a double-logarithmic scale, an example of the voltage response of the equivalent circuit derived from the expression of the voltage response in FIG. 2.

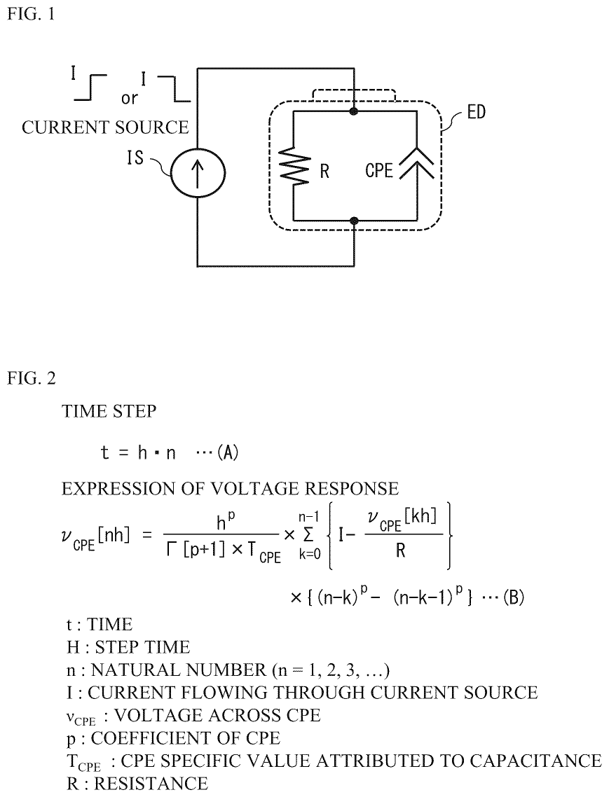

FIG. 3 is a plot illustrating, in a double linear scale, an example of the voltage response of the equivalent circuit derived from the expression of the voltage response in FIG. 2.

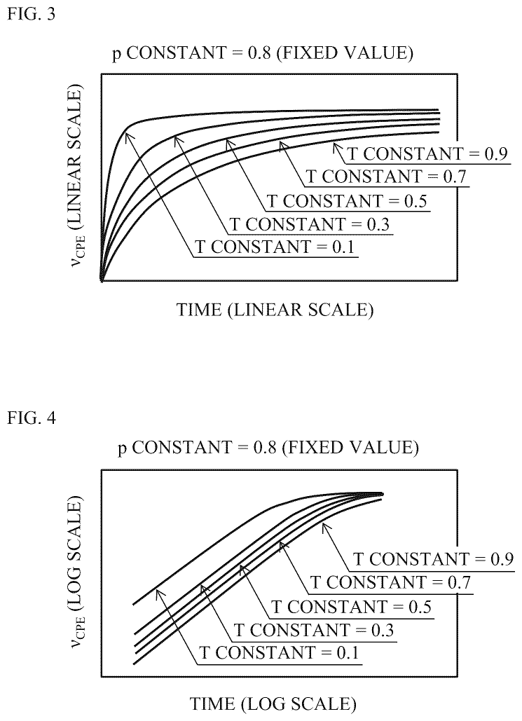

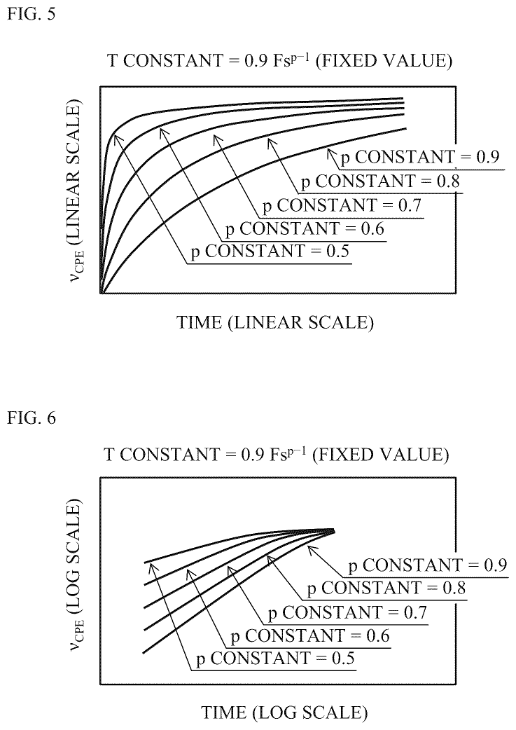

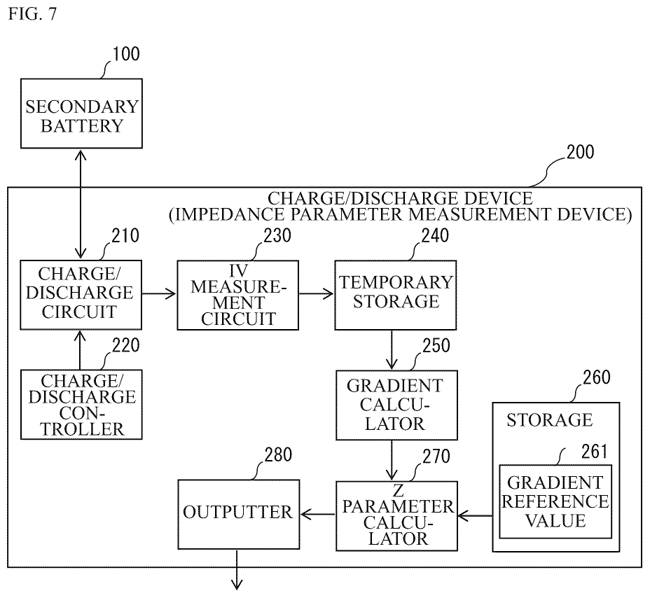

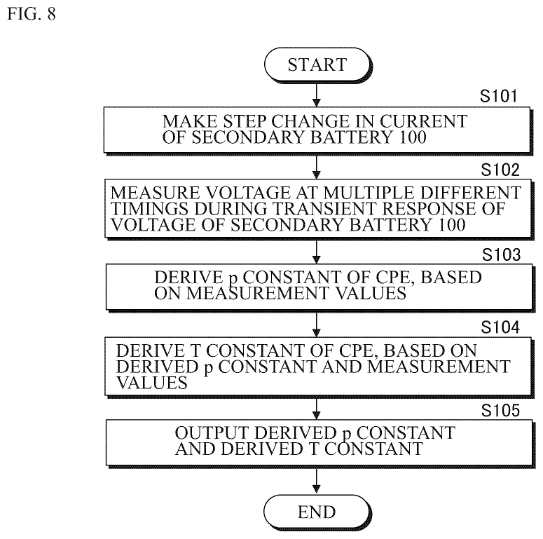

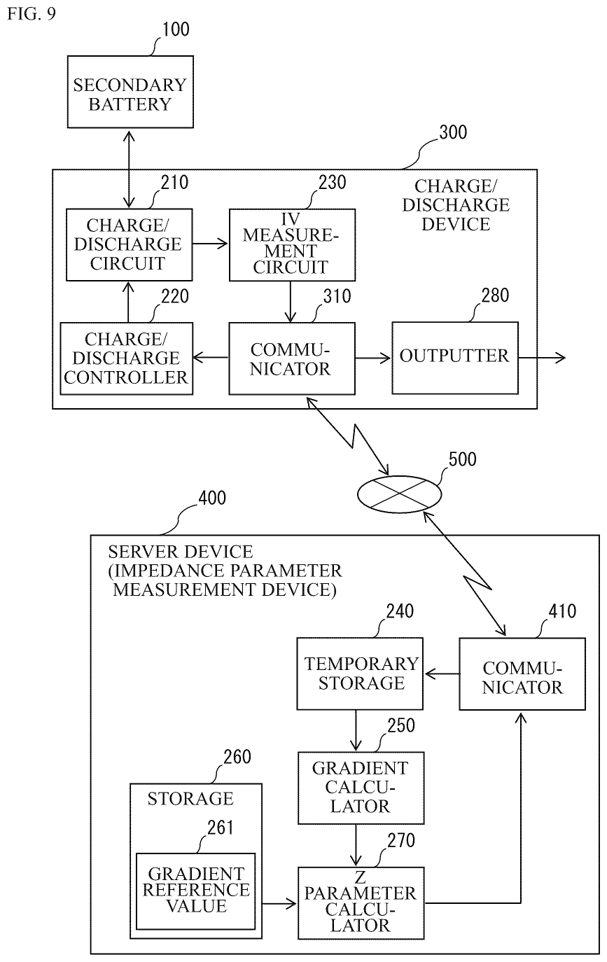

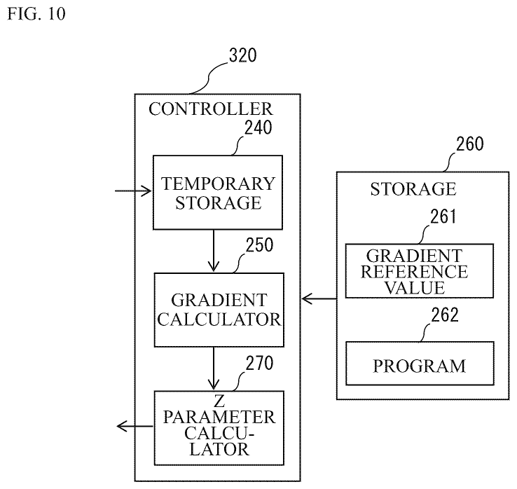

FIG. 4 is a plot illustrating, in a double-logarithmic scale, an example of the voltage response of the equivalent circuit derived from the expression of the voltage response in FIG. 2.

FIG. 5 illustrates an example graph when the T constant is fixed at 0.9 Fsp-1 and the p constant is changed among 0.5, 0.6, 0.7, 0.8, and 0.9 according to embodiment.

FIG. 6 illustrates an example graph when the T constant is fixed at 0.9 Fsp-1 and the p constant is changed among 0.5, 0.6, 0.7, 0.8, and 0.9 according to an embodiment.

FIG. 7 is a diagram illustrating a schematic configuration example of a charge/discharge device according to an embodiment of the present technology.

FIG. 8 is a chart illustrating an example of an operation of the charge/discharge device in FIG. 7.

FIG. 9 is a diagram illustrating a schematic configuration example of an impedance parameter measurement system including a server device according to an embodiment of the present technology.

FIG. 10 is a diagram illustrating an example in which a controller executes respective functions of a temporary storage, a gradient calculator, and a Z parameter calculator in FIGS. 7 and 9.

### DETAILED DESCRIPTION

The present technology is described below in further detail including with reference to the drawings according to an embodiment.

A battery module including many lithium-ion batteries has an issue of decreased safety caused by an abnormal lithium-ion battery mixed therein. One known degradation mode of the lithium-ion battery is a degradation mode in which an electric double layer capacitance greatly changes. It is possible to detect the abnormal lithium-ion battery that degrades due to the degradation mode described above with a focus on a difference in the electric double layer capacitance.

The electric double layer capacitance of the lithium-ion battery is represented by an electric circuit including a constant phase element (CPE) in some cases. The CPE is an element having two constants, i.e., a p constant representing a characteristic as the element and a T constant representing a physical property value. An impedance Z_{CPE} in a frequency domain is represented by the following expression, where j is an imaginary unit, and Φ is an angular frequency.

Z_{CPE}=1/{T×(jω^{P}}

Measuring the p constant and the T constant helps to distinguish between an abnormal lithium-ion battery that degrades due to the degradation mode described above and a normal lithium-ion battery. In general, an alternating-current (AC) impedance method is used to measure the p constant and the T constant. Measurement by the AC impedance method needs a device or a circuit dedicated to the measurement, such as a frequency response analyzer (FRA). Accordingly, it is difficult in terms of cost to mount such a dedicated device or circuit on electronic equipment including the battery module or on a charger for charging the battery module.

The following patent literature discloses deriving a solution in a time domain of an electric circuit including a CPE by non-integer order differentiation (fractional differentiation), not by integer order differentiation such as first order differentiation or second order differentiation. The following non-patent literature discloses deriving a solution in the time domain of an electric circuit including a CPE by use of a Laplace transform.

Patent Literature: Japanese Unexamined Patent Application Publication No. 2011-145944 Non-Patent Literature: Chun-Sing Cheng, Henry Shu-Hung Chung, Ricky Wing-Hong Lau, and Kelvin Yi-Wen Hong, “Time-Domain Modeling of Constant Phase Elements for Simulation of Lithium Battery Behavior,” IEEE Transactions on Power Electronics 34 (8), 2019, pp 7573-7587.

However, the patent literature and the non-patent literature described above each have an issue that it takes long calculation time to calculate a behavior in the time domain of the electric circuit including the CPE. In view of such an issue, the inventors of the present application propose below a method of measuring an impedance parameter and an impedance parameter measurement device each of which makes it possible to measure a p constant and a T constant while achieving reduction in the calculation time according to an embodiment.

FIG. 1 illustrates an equivalent circuit of an electrochemical device ED. The electrochemical device ED is represented by an equivalent circuit including a parallel circuit of a CPE and a resistance (R) as illustrated in FIG. 1. Examples of the electrochemical device ED include a lithium-ion battery (a secondary battery), a dye-sensitized solar cell (a solar cell), and a fuel cell (an electrochemical cell). A current source IS is coupled to the electrochemical device ED, and a current I generated by the current source IS is supplied to the electrochemical device ED. In a case where the electrochemical device ED is the lithium-ion battery (the secondary battery), the current I generated by the current source IS is supplied to the electrochemical device ED when the electrochemical device ED is fully charged.

The current source IS is configured to make a step change in current of the electrochemical device ED. The current source IS may make, for example, a rising change in waveform of the current of the electrochemical device ED as the step change in the current. The current source IS may make, for example, a falling change in the waveform of the current of the electrochemical device ED as the step change in the current.

When the current source IS makes the step change in the current of the electrochemical device ED, a transient response of a voltage of the electrochemical device ED occurs. The transient response continues for several tens of microseconds and thereafter converges to a constant value. It is assumed that the voltage of the electrochemical device ED is measured at multiple (at least two) different timings in a period of several tens of microseconds during the transient response of the voltage of the electrochemical device ED. A double-logarithmic graph of time and voltage is drawn using multiple voltage values thus determined at this time to thereby obtain a linear graph with a gradient α.

Here, it is possible to represent a voltage to be applied to the CPE in the electric circuit including the parallel circuit of the CPE and the resistance (R) by, for example, an expression of a voltage response (C. S. Chenge et al., IEEE Trans. on Power Elec.34 (8), 2019, 7573-7587.) illustrated in FIG. 2. A double linear graph of time and a voltage VCPE is drawn using the voltage VCPE of the CPE determined by this expression to thereby obtain, for example, a curve graph as illustrated in FIG. 3. FIG. 3 illustrates example graphs when the p constant is fixed at 0.8 and the T constant is changed among 0.1, 0.3, 0.5, 0.7, and 0.9. Further, when a double-logarithmic graph of the time and the voltage VCPE is drawn using the voltage VCPE of the CPE determined by the expression described above to thereby obtain, for example, a curve graph as illustrated in FIG. 4. FIG. 4 illustrates example graphs when the p constant is fixed at 0.8 and the T constant is changed among 0.1, 0.3, 0.5, 0.7, and 0.9. It can be seen from FIG. 4 that respective gradients of the graphs are approximately equal in a period before the voltage VCPE of the CPE converges to a constant value.

A double linear graph of time and the voltage VCPE is drawn using the voltage VCPE of the CPE determined by the expression described above to thereby obtain, for example, a curve graph as illustrated in FIG. 5. FIG. 5 illustrates example graphs when the T constant is fixed at 0.9 Fsp-1 and the p constant is changed among 0.5, 0.6, 0.7, 0.8, and 0.9. Further, a double-logarithmic graph of time and the voltage VCPE is drawn using the voltage VCPE of the CPE determined by the expression described above to thereby obtain, for example, a curve graph as illustrated in FIG. 6. FIG. 6 illustrates example graphs when the T constant is fixed at 0.9 Fsp-1 and the p constant is changed among 0.5, 0.6, 0.7, 0.8, and 0.9. It can be seen from FIG. 6 that respective gradients of the graphs are different from each other in a period before the voltage VCPE of the CPE converges to a constant value.

Note that the gradient α determined in a case of making the step change in the current of the electrochemical device ED coincides with the p constant when the resistance R coupled in parallel is considered to be sufficiently large or when a temporal change in the voltage VCPE is considered to be sufficiently small. This can be described by the following expression.

According to the non-patent literature described above, it is possible to represent a transient voltage response of a circuit including the CPE and the resistance R that are coupled in parallel by Expression (1), where n is the number of steps, T is a step time, C is the T constant of the CPE, Φ is the p constant of the CPE, and i is a current.

$${v}_{CPE} [ nT ] = \frac{{T}^{ϕ}}{Γ [ ϕ + 1 ] \times C} \times {\sum }_{k = 0}^{n - 1} \{ i [ kT ] - \frac{{v}_{CPE} [ kT ]}{R} \} \times \{ {( n - k )}^{ϕ} - {( n - k - 1 )}^{ϕ} \} \qquad ( 1 )$$

Here, in a case of a step response, it is assumed that the current i is considered to be a constant and the voltage VCPE in a sigma notation is considered to be a voltage V_{CONST} having a constant value. Alternatively, it is assumed that the R is considered to be sufficiently large and VCPE/R is considered to be zero. In this case, a term including i and V_{CONST} can be taken out of the sigma notation. At this time, Expression (1) can be transformed into Expression (2).

$${v}_{CPE} [ nT ] = \frac{{T}^{ϕ}}{Γ [ ϕ + 1 ] \times C} \times ( i - \frac{{v}_{const}}{R} ) \times {\sum }_{k = 0}^{n - 1} \{ {( n - k )}^{ϕ} - {( n - k - 1 )}^{ϕ} \} \qquad ( 2 )$$

Here, Expression (2) can be transformed into Expression (4) by using a relational expression, i.e., Expression (3).

$${\sum }_{k = 0}^{n - 1} \{ {( n - k )}^{ϕ} - {( n - k - 1 )}^{ϕ} \} = {n}^{ϕ} \qquad ( 3 )$$

$${v}_{CPE} [ nT ] = \frac{{T}^{ϕ}}{Γ [ ϕ + 1 ] \times C} \times ( i - \frac{{v}_{const}}{R} ) \times {n}^{ϕ} \qquad ( 4 )$$

Here, when symbols nT, C, and Φ are respectively replaced with symbols t (an elapsed time), T, and p, Expression (4) is transformed into Expression (5). Further, taking the logarithm of both sides of Expression (5) gives Expression (6). Expression (6) is an expression of a straight line, where p is a gradient of a double-logarithmic plot and the second term on the right-hand side is an intercept.

$${v}_{CPE} = \frac{{t}^{p}}{Γ [ p + 1 ] \times T} \times ( i - \frac{{v}_{const}}{R} ) \qquad ( 5 )$$

$$log {v}_{CPE} = p log t + log \{ \frac{1}{Γ [ p + 1 ] \times T} \times ( i - \frac{{v}_{const}}{R} ) \} \qquad ( 6 )$$

The above demonstrates that it is possible to determine the p constant from the magnitude of the gradient α determined in the case of making the step change in the current of the electrochemical device ED. A description is given below of a device that makes it possible to derive the p constant with use of the gradient α determined in the case of making the step change in the current of the electrochemical device ED and to derive the T constant with use of the derived p constant. In the following description, an example is given of a case where the electrochemical device ED is a lithium-ion battery. However, the electrochemical device ED is not limited to the lithium-ion battery, and may be any other device.

A description is given of a configuration of a charge/discharge device 200 according to a first embodiment of the present technology. FIG. 7 illustrates a schematic configuration example of the charge/discharge device 200. The charge/discharge device 200 is a device that charges and discharges a secondary battery 100. The charge/discharge device 200 corresponds to a specific example of an “impedance parameter measurement device” according to an embodiment of the present technology.

The charge/discharge device 200 has not only a function of charging and discharging the secondary battery 100 but also a function of measuring impedance parameters of the secondary battery 100. The “impedance parameters of the secondary battery” indicate a p constant and a T constant of an equivalent circuit of the secondary battery 100 when the equivalent circuit can be represented by the electric circuit including the parallel circuit of the CPE and the resistance (R).

The secondary battery 100 is a lithium-ion secondary battery. The lithium-ion secondary battery included in the secondary battery 100 may be a unit cell, a battery block in which multiple unit cells are coupled, or an assembled battery in which a battery block and an accessory are integrally packed. The assembled battery includes multiple lithium-ion secondary batteries coupled in series. The assembled battery may include multiple lithium-ion secondary batteries that are electrically coupled in parallel.

As illustrated in FIG. 7, the charge/discharge device 200 includes, for example, a charge/discharge circuit 210, a charge/discharge controller 220, an IV measurement circuit 230, a temporary storage 240, a gradient calculator 250, a storage 260, a Z parameter calculator 270, and an outputter 280.

The charge/discharge circuit 210 includes a charge circuit that charges the secondary battery 100 and a discharge circuit that discharges the secondary battery 100. The charge circuit includes components including, without limitation, a generator and a converter.” The charge/discharge controller 220 is configured to control a current for charging the secondary battery 100 and to control a current for discharging the secondary battery 100. The charge/discharge controller 220 includes, for example, a micro-processing unit (MPU) that controls charging and discharging, or a central processing unit (CPU) with a charge/discharge control program loaded thereto. The charge/discharge controller 220 is configured to control the charge/discharge circuit 210 to make a step change in current of the secondary battery 100. The charge/discharge controller 220 may control the charge/discharge circuit 210 to make, for example, a rising change in waveform of the current of the secondary battery 100 as the step change in the current. The charge/discharge controller 220 may control the charge/discharge circuit 210 to make, for example, a falling change in the waveform of the current of the secondary battery 100 as the step change in the current.

The charge/discharge circuit 210 is configured to make the step change in the current of the secondary battery 100 under the control by the charge/discharge controller 220. The charge/discharge circuit 210 may make, for example, the rising change in the waveform of the current of the secondary battery 100 as the step change in the current under the control by the charge/discharge controller 220. The charge/discharge circuit 210 may make, for example, the falling change in the waveform of the current of the secondary battery 100 as the step change in the current under the control by the charge/discharge controller 220.

The IV measurement circuit 230 includes a measurement circuit that is configured to measure a current and a voltage of the secondary battery 100. For example, the IV measurement circuit 230 is configured to measure the current and the voltage during a transient response of the voltage of the secondary battery 100 caused by making the step change in the current of the secondary battery 100. Here, the transient response continues for several tens of microseconds and thereafter converges to a constant value. The IV measurement circuit 230 is configured to measure the voltage of the secondary battery 100 at multiple (at least two) different timings in a period of several tens of microseconds in which the transient response of the voltage of the secondary battery 100 occurs. That is, a period in which the IV measurement circuit 230 measures the voltage of the secondary battery 100 at multiple (at least two) different timings is a period of several tens of microseconds or less from when the step change in the current of the secondary battery 100 is made.

The gradient calculator 250 is configured to derive the gradient α in a double-logarithmic graph of time and voltage, based on multiple voltage values determined through measurement by the IV measurement circuit 230. The gradient calculator 250 includes, for example, a CPU with a program for deriving the gradient α loaded thereto.

The storage 260 includes a volatile memory such as a dynamic random access memory (DRAM) or a nonvolatile memory such as an electrically erasable programmable read-only memory (EEPROM) or a flash memory. For example, a gradient reference value 261 is stored in the storage 260. The gradient reference value 261 includes a table in which a gradient and a p constant are associated with each other. The table includes multiple gradients having different magnitudes and multiple p constants each associated with a corresponding one of the gradients.

The Z parameter calculator 270 is configured to derive a p constant of the CPE of the equivalent circuit of the secondary battery 100, based on the gradient α determined by the gradient calculator 250. The Z parameter calculator 270 is configured to read a p constant corresponding to the gradient α determined by the gradient calculator 250 from the gradient reference value 261 stored in the storage 260 and use the thus read p constant as the p constant of the CPE of the equivalent circuit of the secondary battery 100.

The Z-parameter calculator 270 is configured to derive a T constant of the CPE of the equivalent circuit of the secondary battery 100, based on the derived p constant and the multiple voltage values determined through the measurement by the IV measurement circuit 230. The Z parameter calculator 270 is configured to derive the T constant using, for example, the following expression (see the non-patent literature described above). Here, AI is a current change amount before and after the step change in the current, ΔV is a voltage change amount after the step change in the current, At is an elapsed time after the current step, and I′ is a I function.

T=(ΔI/ΔV)×{Δt^{P}/T(p+1)}

The outputter 280 is an output interface that outputs the impedance parameters (the p constant and the T constant) determined by the Z parameter calculator 270 to an outside.

A description is given next of measurement of the impedance parameters of the secondary battery 100 by the charge/discharge device 200.

FIG. 8 illustrates an example of a measurement procedure of the impedance parameters of the secondary battery 100 by the charge/discharge device 200. First, the charge/discharge circuit 210 makes the step change in the current of the secondary battery 100 (step S101). Thereafter, the IV measurement circuit 230 measures the voltage at multiple different timings during the transient response of the voltage of the secondary battery 100 caused by making the step change in the current of the secondary battery 100 (step S102).

Thereafter, the gradient calculator 250 derives the gradient α in the double-logarithmic graph of time and voltage, based on the multiple voltage values determined through the measurement by the IV measurement circuit 230. Thereafter, the Z parameter calculator 270 derives the p constant of the CPE of the equivalent circuit of the secondary battery 100, based on the gradient α determined by the gradient calculator 250 (step S103). The Z parameter calculator 270 further derives the T constant of the CPE of the equivalent circuit of the secondary battery 100, based on the derived p constant and the multiple voltage values determined through the measurement by the IV measurement circuit 230 (step S104). The outputter 280 outputs the impedance parameters (the p constant and the T constant) determined by the Z parameter calculator 270 to the outside (step S105). The impedance parameters of the secondary battery 100 are thus measured by the charge/discharge device 200.

A description is given next of effects of the charge/discharge device 200 according to an embodiment.

In the present embodiment, the voltage of the secondary battery 100 is measured at the multiple different timings during the transient response of the voltage of the secondary battery 100 caused by making the step change in the current of the secondary battery 100. The secondary battery 100 is represented by the equivalent circuit that is the electric circuit including the CPE. Thereafter, the p constant of the CPE is derived, based on the multiple voltage values determined through the measurement, and the T constant of the CPE is derived, based on the derived p constant and the multiple voltage values determined through the measurement. This makes it possible to measure the p constant and the T constant while achieving reduction in calculation time.

In the present embodiment, the p constant of the CPE is derived, based on the gradient α in the double-logarithmic graph of time and voltage obtained from the multiple voltage values determined through the measurement. This makes it possible to measure the p constant and the T constant while achieving reduction in the calculation time.

In the present embodiment, the period in which the multiple voltage values are measured is a period of several tens of microseconds or less from when the step change in the current of the secondary battery 100 is made. In the present embodiment, the p constant and the T constant are thus derived, based on the transient response in a very short period of time. It is therefore possible to measure the p constant and the T constant in a short time while achieving reduction in the calculation time.

In the present embodiment, the rising change in the waveform of the current of the secondary battery 100 is made as the step change in the current. This makes it possible to measure the p constant and the T constant in a short time while achieving reduction in the calculation time.

In the present embodiment, the falling change in the waveform of the current of the secondary battery 100 is made as the step change in the current. This makes it possible to measure the p constant and the T constant in a short time while achieving reduction in the calculation time.

A description is given next of an impedance parameter measurement system including a server device 400 as an impedance parameter measurement device according to a second embodiment of the present technology. FIG. 9 illustrates a schematic configuration example of the impedance parameter measurement system according to the present embodiment.

The impedance parameter measurement system includes the secondary battery 100, a charge/discharge device 300, and the server device 400. The charge/discharge device 300 and the server device 400 are coupled to each other via a communication network 500. The charge/discharge device 300 and the server device 400 are communicable with each other via the communication network 500. The communication network 500 includes, for example, any one of networks including, without limitation, the Internet, a cloud network, and a carrier-specific network.

The charge/discharge device 300 is a device that charges and discharges the secondary battery 100, and is a network communication device having a function of communicating with an external device. As illustrated in FIG. 9, the charge/discharge device 300 includes, for example, the charge/discharge circuit 210, the charge/discharge controller 220, the IV measurement circuit 230, a communicator 310, and the outputter 280. The charge/discharge circuit 210 corresponds to the charge/discharge circuit 210 according to an embodiment described above. The charge/discharge controller 220 corresponds to the charge/discharge controller 220 according to an embodiment described above. The IV measurement circuit 230 corresponds to the IV measurement circuit 230 according to an embodiment described above. The communicator 310 is a communication interface that is communicable with the server device 400 via the communication network 500. The communicator 310 is configured to output, to the outputter 280, impedance parameters transmitted from the server device 400.

As illustrated in FIG. 9, the server device 400 includes, for example, the temporary storage 240, the gradient calculator 250, the storage 260, the Z parameter calculator 270, and a communicator 410. The temporary storage 240 corresponds to the temporary storage 240 according to an embodiment described above. The gradient calculator 250 corresponds to the gradient calculator 250 according to an embodiment described above. The Z parameter calculator 270 corresponds to the Z parameter calculator 270 according to an embodiment described above. The communicator 410 is a communication interface that is communicable with the charge/discharge device 300 via the communication network 500. The communicator 410 is configured to transmit impedance parameters determined by the Z parameter calculator 270 to the charge/discharge device 300.

In the present embodiment, the server device 400 is provided with respective functions of the temporary storage 240, the gradient calculator 250, the storage 260, and the Z parameter calculator 270. Also in such a case, it is possible to measure the p constant and the T constant while achieving reduction in calculation time, as in an embodiment described above.

In an embodiment, for example, the controller 320 may execute the respective functions of the temporary storage 240, the gradient calculator 250, and the Z parameter calculator 270, as illustrated in FIG. 10. In this case, the controller 320 includes, for example, an MPU, or a CPU with a program 262 loaded thereto. The MPU is configured to execute the respective functions of the temporary storage 240, the gradient calculator 250, and the Z parameter calculator 270. A series of respective operations of the temporary storage 240, the gradient calculator 250, and the Z parameter calculator 270 is written in the program 262. The program 262 is stored in the storage 260, for example.

Note that in an embodiment including modification example thereof, an object for which the impedance parameters are to be determined is the secondary battery 100. However, in an embodiment including modification example thereof, the object for which the impedance parameters are to be determined is not limited to the secondary battery 100, and may be any other electrochemical device.

Note that the present technology may have any of the following configurations according to an embodiment.

<1>

A method of measuring an impedance parameter of an electrochemical device represented by an equivalent circuit that is an electric circuit including a constant phase element, the method including:
making a step change in current of the electrochemical device;
performing measurement of a voltage of the electrochemical device at multiple different timings during a transient response of the voltage of the electrochemical device caused by making the step change in the current of the electrochemical device; and
deriving a p constant of the constant phase element, based on multiple voltage values determined through the measurement, and deriving a T constant of the constant phase element, based on the derived p constant and the multiple voltage values determined through the measurement.
   <2>

The method of measuring the impedance parameter according to <1>, in which the deriving of the p constant of the constant phase element includes deriving the p constant of the constant phase element, based on a gradient in a double-logarithmic graph of time and voltage obtained from the multiple voltage values determined through the measurement.

<3>

The method of measuring the impedance parameter according to <1> or <2>, in which a period of the measurement is a period of several tens of microseconds or less from when the step change in the current of the electrochemical device is made.

<4>

The method of measuring the impedance parameter according to any one of <1> to <3>, in which the making of the step change in the current of the electrochemical device includes making a rising change in waveform of the current of the electrochemical device as the step change in the current.

<5>

The method of measuring the impedance parameter according to any one of <1> to <3>, in which the making of the step change in the current of the electrochemical device includes making a falling change in waveform of the current of the electrochemical device as the step change in the current.

<6>

An impedance parameter measurement device for an electrochemical device represented by an equivalent circuit that is an electric circuit including a constant phase element, the impedance parameter measurement device including:
a current source configured to make a step change in current of the electrochemical device;
a measurement circuit configured to perform measurement of a voltage of the electrochemical device at multiple different timings during a transient response of the voltage of the electrochemical device caused by making the step change in the current of the electrochemical device; and
a signal processor configured to derive a p constant of the constant phase element, based on multiple voltage values determined through the measurement and to derive a T constant of the constant phase element, based on the derived p constant and the multiple voltage values determined through the measurement.

The effects described herein are mere examples, and effects of the present technology are therefore not limited to those described herein. Accordingly, the present technology may achieve other effects.

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A method of measuring an impedance parameter of an electrochemical device represented by an equivalent circuit that is an electric circuit including a constant phase element, the method comprising:
making a step change in current of the electrochemical device;
performing measurement of a voltage of the electrochemical device at multiple different timings during a transient response of the voltage of the electrochemical device caused by making the step change in the current of the electrochemical device; and
deriving a p constant of the constant phase element, based on multiple voltage values determined through the measurement, and deriving a T constant of the constant phase element, based on the derived p constant and the multiple voltage values determined through the measurement.

2. The method of measuring the impedance parameter according to claim 1, wherein the deriving of the p constant of the constant phase element comprises deriving the p constant of the constant phase element, based on a gradient in a double-logarithmic graph of time and voltage obtained from the multiple voltage values determined through the measurement.

3. The method of measuring the impedance parameter according to claim 1, wherein a period of the measurement is a period of several tens of microseconds or less from when the step change in the current of the electrochemical device is made.

4. The method of measuring the impedance parameter according to claim 1, wherein the making of the step change in the current of the electrochemical device comprises making a rising change in waveform of the current of the electrochemical device as the step change in the current.

5. The method of measuring the impedance parameter according to claim 1, wherein the making of the step change in the current of the electrochemical device comprises making a falling change in waveform of the current of the electrochemical device as the step change in the current.

6. An impedance parameter measurement device for an electrochemical device represented by an equivalent circuit that is an electric circuit including a constant phase element, the impedance parameter measurement device comprising:
a current source configured to make a step change in current of the electrochemical device;
a measurement circuit configured to perform measurement of a voltage of the electrochemical device at multiple different timings during a transient response of the voltage of the electrochemical device caused by making the step change in the current of the electrochemical device; and
a signal processor configured to derive a p constant of the constant phase element, based on multiple voltage values determined through the measurement and to derive a T constant of the constant phase element, based on the derived p constant and the multiple voltage values determined through the measurement.
